(19) United States
(12) Patent Application Publication
(10) Pub. No.: US 2026/0198217 A1
(43) Pub. Date: Jul. 9, 2026

(54) Light Emitting Device, Preparation Method and Electronic Apparatus

(71) Applicant: NAJING TECHNOLOGY CORPORATION LIMITED, Hangzhou, Zhejiang (CN)

(72) Inventor: Yuan GAO, Hangzhou, Zhejiang (CN)

(21) Appl. No.: 18/862,544

(22) PCT Filed: Aug. 3, 2023
(86) PCT No.: PCT/CN2023/111118

§ 371 Date: Nov. 3, 2024

(51) Int. Cl. H10K 71/15; H10K 50/115; H10K 59/12; H10K 59/35

(52) U.S. Cl. CPC H10K 71/15; H10K 50/115; H10K 59/1201; H10K 59/35

(57) ABSTRACT

A light emitting device, its preparation method, and an electronic apparatus are disclosed. The light emitting device of the present disclosure is prepared by providing a substrate provided with a first electrode; forming a light emitting layer, the preparation of the light emitting layer including: forming a first material layer including a first luminescent material on top of the first electrode, removing at least a portion of an exposure area or at least a portion of the first material layer in an non-exposure area by a first solvent; forming a second material layer including a second luminescent material on top of the first electrode, removing at least a portion of an exposure area or at least a portion of the second material layer of an non-exposure area by a second solvent; and a second solvent having a polarity different from a polarity of the first luminescent material.

### TECHNICAL FIELD

The present disclosure relates to the field of optoelectronic apparatus, and specifically to a light emitting device, a preparation method and an electronic apparatus.

### BACKGROUND

Light emitting devices such as light emitting diodes are widely used in the display field. In display devices, the light emitting layer prepared by photolithography will be sufficiently rinsed in the rinsing step in the development process to reduce the occurrence of color mixing, but the degree of rinsing will affect the performance of the device.

### SUMMARY

An object of the present disclosure is to provide a light emitting device, a preparation method and an electronic apparatus, which can solve the technical problem of poor performance of current light emitting device devices.

According to a first aspect of the present disclosure, there is provided a method of preparing a light emitting device, the method includes:
a substrate provided with a first electrode is provided;
a light emitting layer is formed on a side of the first electrode away from the substrate;
the preparation of the light emitting layer includes:
a first material layer including a first luminescent material is formed on top of the first electrode, an exposure area and a non-exposure area are formed in the first material layer, and at least a portion of the exposure area or at least a portion of the non-exposure area of the first material layer is removed by a first solvent to obtain a first light emitting unit;
a second material layer including a second luminescent material is formed on top of the first electrode, an exposure area and a non-exposure area are formed in the second material layer, and at least a portion of the exposure area or at least a portion of the non-exposure area of the second material layer is removed by a second solvent to obtain a second light emitting unit;
a second electrode is formed above the light emitting layer;
the first light emitting unit and the second light emitting unit are disposed along a first direction of the substrate, the first light emitting unit is used to emit light in a first wavelength range, the second light emitting unit is used to emit light in a second wavelength range, the first wavelength range being different from the second wavelength range and a polarity of the second solvent being different from a polarity of the first luminescent material.

Optionally, the preparation of the light emitting layer further includes: a third material layer including a third luminescent material is formed on top of the first electrode.

In some embodiments, an exposure area and a non-exposure area are formed in the third material layer, and at least a portion of the exposure area or at least a portion of the non-exposure area of the third material layer is removed by a third solvent to obtain a third light emitting unit;
the third light emitting unit is used to emit light in a third wavelength range, the third wavelength range being different from the first wavelength range and the second wavelength range;
a polarity of the third solvent being different from the polarity of the first luminescent material and the polarity of the second luminescent material.

In some embodiments, the first luminescent material, the second luminescent material, or the third luminescent material includes a quantum dot material.

Optionally, the quantum dot material includes at least one of CdSe/ZnSe, CdSe/ZnS, CdSe/ZnSe/ZnS, CdS/ZnSe, CdS/ZnS, ZnSe/ZnS, ZnTeSe/ZnS, InP/ZnSe/ZnS and InP/ZnS.

Optionally, a ligand of the quantum dot material includes at least one of an alkyl carboxylic acid, an alkyl phosphonic acid, an alkyl phosphinic acid, an alkyl mercaptan, an alkylamine, an acrylate-substituted acid, a halogen, a mercapto alcohol, a carboxy alcohol, and an amino alcohols.

Optionally, the first solvent, the second solvent, or the third solvent includes at least one of a hydrocarbon solvent, an alkyl alcohol solvent, an ether solvent, an anacetal solvent, a halogenated hydrocarbon solvent, an ester solvent, and a nitrogen-containing compound solvent.

Optionally, the polarity of the first luminescent material is different from the second solvent and the third solvent.

Optionally, the first material layer, the second material layer or the third material layer includes a photosensitive cross-linker.

Optionally, the photosensitive cross-linker includes at least one of an azide compound and a free radical photoinitiator.

Optionally, the substrate has a plurality of isolation structures and the light emitting layer is divided into a plurality of light emitting units by the isolation structures.

Optionally, the isolation structure has a first surface, the material of the first surface being amphiphilic.

Optionally, a first functional layer is formed between the first electrode and the light emitting layer, the first functional layer including at least one of a hole injection layer, a hole transport layer, a hole blocking layer, an electron injection layer, an electron transport layer, an electron blocking layer and a buffer layer.

Optionally, a second functional layer is formed between the light emitting layer and the second electrode, the second functional layer including at least one of a hole injection layer, a hole transport layer, a hole blocking layer, an electron injection layer, an electron transport layer, an electron blocking layer and a buffer layer.

Optionally, a concentration of the quantum dot material is 1 to 50 wt %.

A light emitting device according to a second aspect of the present disclosure, the light emitting device is prepared by the methods described above.

An electronic apparatus according to a third aspect of the present disclosure, the electronic apparatus includes the light emitting device described above.

The method of preparing a light emitting device according to embodiments of the present disclosure has at least the following technical effects.

The present disclosure reduces the loss of performance of the luminescent material in the rinsing process, improves the external quantum efficiency of the light emitting device, and enhances the luminescent performance of the light emitting device by using luminescent materials and rinsing solvents with different polarities in the preparation of different light emitting units.

### BRIEF DESCRIPTION OF DRAWINGS

In order to more clearly illustrate the technical solutions in the embodiments of the present disclosure, the accompanying drawings to be used in the description of the embodiments will be briefly introduced below, and it will be obvious that the accompanying drawings in the following description are only some of the embodiments of the present disclosure, and other accompanying drawings can be obtained according to these drawings for the person of ordinary skill in the art without giving creative labor.

FIG. 1 shows a flowchart of the preparation of a light emitting device in some embodiments of the present disclosure.

FIG. 2 shows a flowchart of the preparation of a light emitting device in some embodiments of the present disclosure.

FIG. 3 shows a flowchart of the preparation of the light emitting device in some embodiments of the present disclosure.

FIG. 4 shows a flowchart of the preparation of the light emitting device in some embodiments of the present disclosure.

FIG. 5 shows a flowchart of the preparation of the light emitting device in some embodiments of the present disclosure.

FIG. 6 shows a flow chart of the preparation of the light emitting device in some embodiments of the present disclosure.

FIG. 7 shows a flowchart of the preparation of the light emitting device in some embodiments of the present disclosure.

FIG. 8 shows a schematic diagram of the structure of the light emitting device in some embodiments of the present disclosure.

FIG. 9 shows a flowchart of the preparation of the light emitting device in some other embodiments of the present disclosure.

FIG. 10 shows a schematic diagram of the structure of the light emitting device in some other embodiments of the present disclosure.

FIG. 11 shows a schematic diagram of the structure of the light emitting device in some other embodiments of the present disclosure.

In the figures, 100—substrate, 101—isolation structure, 110—first surface, 200—first electrode, 300—light emitting layer, 301—first light emitting unit, 302—second light emitting unit, 303—third light emitting unit, 400—second electrode, 500—first functional layer, 501—hole injection layer, 502—hole transport layer, 600—second functional layer.

### DETAILED DESCRIPTION

The technical solutions in the embodiments of the present disclosure will be described clearly and completely in the following in conjunction with the accompanying drawings in the embodiments of the present disclosure, and it is obvious that the described embodiments are only a part of the embodiments of the present disclosure, and not all of the embodiments. Based on the embodiments in this disclosure, all other embodiments obtained by a person of ordinary skill in the art without making creative labor fall within the scope of protection of this disclosure. Furthermore, in the description of the present disclosure, the term “include” means “including but not limited to”. The terms “first”, “second”, “third”, etc. are used merely as indications and do not impose numerical requirements or establish an order. Various embodiments of the present disclosure may exist in the form of a range; it should be understood that the description in the form of a range is for convenience and brevity only, and should not be construed as a rigid limitation of the scope of the present disclosure; therefore, the description of the range as described should be considered to specifically disclose all possible sub-ranges as well as a single numerical value within that range. For example, the description of the range from 1 to 6 should be considered to specifically disclose sub-ranges, such as from 1 to 3, from 1 to 4, from 1 to 5, from 2 to 4, from 2 to 6, from 3 to 6, and so forth, as well as a single number within the numerical ranges, such as 1, 2, 3, 4, 5, and 6, which applies irrespective of the range. In addition, whenever a numerical range is indicated herein, it is meant to include any quoted number (fraction or integer) within the indicated range.

The “left”, “right”, “front”, “back”, “top”, “bottom”, “up”, “down”, “high”, “low”, etc., referred to in this disclosure, if they exist, are used for descriptive purposes and not necessarily to describe unchanging relative positions. It should be understood that the words so used are interchangeable where appropriate, enabling the embodiments of the present disclosure described herein, for example, to operate in other orientations than those shown or otherwise described herein. For example, when the device in the accompanying drawings is inverted, features originally described as being “above” other features may be described as being “below” other features. The device may also be oriented in other ways (rotated 90 degrees or in other orientations), at which point the relative spatial relationships will be interpreted accordingly. References in this disclosure to one element being “on top of” another element, that element may be directly on top of another element, or one or more intermediate elements may be present. Furthermore, the accompanying drawings of the present disclosure show a cross-sectional view of only a portion of the light emitting device. In the present disclosure, the first direction X is transverse, the second direction Y is longitudinal, the second direction Y is also the thickness direction of the respective structures, the first direction X and the second direction Y intersect, or the first direction X and the second direction Y are perpendicular or relatively perpendicular.

The light emitting device is a structure in which various functional layers are laminated on a substrate 100 on which a TFT (Thin Film Transistor) is formed, and the areas surrounded by the isolation structures 101 provided on the substrate 100 are pixel areas of various colors, the pixel areas may be of various shapes, and a plurality of pixel areas may form an array. Taking a light emitting device having RGB pixel areas as an example, the substrate 100 is divided by the isolation structures 101 into a red pixel area RP, a green pixel area GP, and a blue pixel area BP. The different pixel areas are subject to a greater loss of performance of the light emitting device when the different pixel areas are rinsed more thoroughly during the preparation process to minimize the occurrence of color mixing. In order to solve the above problem, the present disclosure provides a method of preparing a light emitting device, including: a substrate 100 is provided with a first electrode 200; a light emitting layer 300 is formed on a side of the first electrode 200 that is away from the substrate 100; the preparation of the light emitting layer 300 includes: a first material layer including a first luminescent material is formed on top of the first electrode 200, an exposure area and a non-exposure area are formed in the first material layer, at least a portion of the exposure area or at least a portion of the non-exposure area of the first material layer are removed by a first solvent, and a first light emitting unit 301 is obtained; a second material layer including a second luminescent material is formed on top of the first electrode 200, an exposure area and a non-exposure area are formed in the second material layer, at least a portion of the exposure area or at least a portion of the non-exposure area of the second material layer are removed by a second solvent, and a second light emitting unit 302 is obtained; a second electrode 400 is formed above the light emitting layer 300.

The first light emitting unit 301 and the second light emitting unit 302 are provided along a first direction X of the substrate 100, the first light emitting unit 301 is used to emit light in a first wavelength range, the second light emitting unit 302 is used to emit light in a second wavelength range, the first wavelength range is different from the second wavelength range, and a polarity of the second solvent is different from a polarity of the first luminescent material.

In some embodiments, the light emitting device of the present disclosure is a structure in which layers are laminated on a substrate 100 on which a TFT (Thin Film Transistor) is formed, the first electrode 200 is electrically connected to the TFT, and the substrate 100 is a patterned array substrate. In some embodiments, the first electrode 200 is an anode and is light transmissive, and the first electrode 200 may also include a transparent oxide such as, for example, ITO, IZO, or AZO. In addition, the first electrode 200 may include one or more layers of conductive material.

In the present disclosure, the polarity of the second solvent is different from the polarity of the first luminescent material, the second solvent is a non-polar solvent and the first material is a polar material, or, the second solvent is a polar solvent and the first material is a non-polar material. The light emitting device of the present disclosure employs luminescent material and rinsing solvent with different polarities when preparing different light emitting units, which reduces the loss of performance of the luminescent materials caused by rinsing, improves the external quantum efficiency of the light emitting device, and enhances the light emitting performance of the light emitting device.

In some embodiments, the preparation of the light emitting layer 300 further includes: a third material layer including a third luminescent material is formed on top of the first electrode 200.

In some embodiments, the following steps are applied to the third material layer: an exposure area and a non-exposure area are formed in the third material layer, at least a portion of the exposure area or at least a portion of the non-exposure area of the third material layer are removed by a third solvent to obtain a third light emitting unit 303; the third light emitting unit 303 is used to emit light in a third wavelength range, the third wavelength range being different from the first wavelength range and the second wavelength range; a polarity of the third solvent is different from the polarity of the first luminescent material or the polarity of the second luminescent material. The present disclosure reduces the loss of performance of the light emitting units in the rinsing process by using luminescent material and rinsing solvent with different polarities when preparing different light emitting units.

In some embodiments, the first material layer, the second material layer, or the third material layer, after forming the exposure area and the non-exposure area, is subjected to a drying or baking process to remove the solvent from the first material layer, the second material layer, or the third material layer, wherein the solvent is used to dispersing or dissolving the luminescent material in the material layer.

In some embodiments, the light emitting layer 300 includes a first light emitting unit 301, a second light emitting unit 302, and a third light emitting unit 303, with the first light emitting unit 301, the second light emitting unit 302, and the third light emitting unit 303 being disposed along the first direction X.

In some embodiments, the first light emitting unit 301 is used to emit light in the first wavelength range, the second light emitting unit 302 is used to emit light in the second wavelength range, and the third light emitting unit 303 is used to emit light in a third wavelength range. In some specific embodiments, the first wavelength range is from 600 to 780 nm, the first light emitting unit is used to emit red light, the second wavelength range is from 500 to 600 nm, the second light emitting unit 302 is used to emit green light, the third wavelength range is from 400 to 500 nm, and the third light emitting unit 303 is used to emit blue light.

In some embodiments, the first light emitting unit 301, the second light emitting unit 302, or the third light emitting unit 303 in the present disclosure are formed by positive lithography. Taking the first light emitting unit 301 as an example, the first light emitting unit 301 is prepared by the followings: forming a first material layer including a first luminescent material on top of the first electrode 200, having a patterned mask disposed on top of the first material layer, exposing, forming an exposure area and a non-exposure area in the first material layer, removing the exposure area by a first solvent, retaining the non-exposure area under the opaque mask, the retained first material layer forming the first light emitting unit 301. The second light emitting unit 302 or the third light emitting unit 303 may be prepared using the same preparation method as that of the first light emitting unit 301, or, the second light emitting unit 302 or the third light emitting unit 303 may be prepared using a different preparation method than that of the first light emitting unit 301.

In some embodiments, the first light emitting unit 301, the second light emitting unit 302, or the third light emitting unit 303 in the present disclosure are formed by negative lithography. Taking the first light emitting unit 301 as an example, the first light emitting unit 301 is prepared by the followings: forming a first material layer including a first luminescent material on top of the first electrode 200, having a patterned mask disposed on top of the first material layer, exposing, forming an exposure area and a non-exposure area in the first material layer, the exposure area being cross-linked and cured as a result of the exposure, and removing the non-exposure area by a first solvent. The retained exposure area of the first material layer forms a first light emitting unit 301. The second light emitting unit 302 or the third light emitting unit 303 may be prepared using the same preparation method as that of the first light emitting unit 301, or, the second light emitting unit 302 or the third light emitting unit 303 may be prepared using a different preparation method than that of the first light emitting unit 301.

In some embodiments, the first luminescent material, the second luminescent material, or the third luminescent material includes a quantum dot material. In some specific embodiments, the quantum dot material includes an RQD (red quantum dot), a GQD (green quantum dot), and a BQD (blue quantum dot). The RQD, the GQD, and the BQD emit light in different wavelengths and emit red, green, and blue light, respectively. In addition to the RQD, GQD, and BQD, the light emitting layer may also include, for example, quantum dots that emit yellow light. The quantum dot material may include a Group II-VI semiconductor compound, a Group III-V semiconductor compound, a Group III-VI semiconductor compound, a Group I-III-VI semiconductor compound, a Group IV-VI semiconductor compound, a Group IV element or compound; or any combination thereof. In other specific embodiments, the RQD, GQD, and BQD have a core-shell structure and may include at least one of, for example, CdSe/ZnSe, CdSe/ZnS, CdS/ZnSe, CdS/ZnS, ZnTeSe/ZnS, InP/ZnSe/ZnS, and InP/ZnS.

In some embodiments, the first luminescent material is selected from a non-polar quantum dot material, the first solvent is selected from a non-polar solvent, the second luminescent material is selected from a polar quantum dot material, the second solvent is selected from a polar solvent, the third luminescent material is selected from a polar quantum dot material, and the third solvent is selected from a polar solvent; or, the first luminescent material is selected from a polar quantum dot material, the first solvent is selected from a polar solvent, the second luminescent material is selected from a non-polar quantum dot material, the second solvent is a non-polar solvent, the third luminescent material is a non-polar quantum dot material, and the third solvent is a non-polar solvent; or, the first luminescent material is a polar quantum dot material, the first solvent is a polar solvent, the second luminescent material is a non-polar quantum dot material, the second solvent is a non-polar solvent, the third luminescent material is a polar quantum dot material, and the third solvent is a polar solvent; or, the first luminescent material is selected from polar quantum dot material, the first solvent is selected from a polar solvent, the second luminescent material is selected from a polar quantum dot material, the second solvent is selected from of polar solvents, the third luminescent material is selected from a non-polar quantum dot material, the third solvent is selected from a non-polar solvent; or, the first luminescent material is selected from a non-polar quantum dot material, the first solvent is selected from a non-polar solvent, the second luminescent material is selected from a non-polar quantum dot material, the second solvent is selected from a non-polar solvent, the third luminescent material is selected from a polar quantum dot material, the third solvent is selected from a polar solvent; or, the first luminescent material is selected from a non-polar quantum dot material, the first solvent is selected from a non-polar solvent, the second luminescent material is selected from a polar quantum dot material, the second solvent is selected from a polar solvent, and the third luminescent material is selected from a non-polar quantum dot material, and the third solvent is selected from a non-polar solvent.

In this disclosure, the polarity of a substance can be characterized by the dielectric constant of the substance. When the dielectric constant & of the substance satisfies: 0<ε≤5, the substance is a non-polar substance. When the dielectric constant & of the substance satisfies: 5<ε≤100, the substance is a polar substance.

In some embodiments, a ligand of the quantum dot material includes at least one of a non-polar ligand or a polar ligand. In some embodiments, the solvent solubility property of the quantum dot material is primarily determined by its surface ligands, such as in other embodiments, where the polarity of the luminescent material means that the ligands on the surface of the quantum dots are polar ligands or non-polar ligands.

Non-polar ligands include alkyl carboxylic acids, alkyl phosphonic acids, alkyl phosphinic acids, alkyl thiols, or alkyl amines. Alkyl groups in this disclosure include saturated branched alkyl groups, branched alkyl groups, unsaturated alkyl groups, and in some embodiments, the alkyl groups described in this paragraph have a number of carbon atoms from 1 to 18.

In some embodiments, alkyl carboxylic acids include saturated alkyl carboxylic acids, branched alkyl carboxylic acids, unsaturated alkyl carboxylic acids, such as oleic acid. Alkyl phosphonic acids include saturated alkyl phosphonic acids, branched alkyl phosphonic acids, and unsaturated alkyl phosphonic acids, such as octyl phosphonic acid. Alkyl phosphinic acids include saturated alkyl phosphinic acids, branched alkyl phosphinic acids, and unsaturated alkyl phosphinic acids, such as hexyl phosphinic acid, octyl phosphinic acid, and dodecyl phosphinic acid. Alkyl mercaptans include saturated alkyl mercaptans, branched chain alkyl mercaptans, such as 2-ethylhexyl mercaptan, octyl mercaptan, nonyl mercaptan, decyl mercaptan, undecyl mercaptan, dodecyl mercaptan, tridecyl mercaptan, tetradecyl mercaptan, hexadecyl mercaptan, or octadecyl mercaptan. Alkyl amines include saturated alkyl amines, branched alkyl amines, unsaturated alkyl amines such as oleyl amine, and the like.

Polar ligands include acrylate-substituted acids, halogens, mercapto alcohols, carboxy alcohols, or amino alcohols. Acrylate-substituted acids include acrylic acid, mono-2-(methacryloyloxy)ethyl succinate, 4-oxo-4-[2-(prop-2-enoyloxy) ethoxy]butanoic acid, and the like. Halogens include fluorine, chlorine, bromine, and iodine. Mercapto alcohols include 2-mercaptoethanol, 3-mercapto-1-propanol, 4-mercapto-1-butanol, 5-mercapto-1-pentanol, 6-mercapto-1-hexanol, 8-mercapto-1-octanol, and the like. Carboxy alcohols include ethanoic acid, hydroxypropionic acid, hydroxybutyric acid, hydroxyvaleric acid, hydroxyhexanoic acid, hydroxyoctanoic acid, hydroxyheptanoic acid, hydroxybenzoic acid, hydroxyphenylacetic acid, hydroxyphenylpropionic acid, hydroxybutyric acid, hydroxyphenylacetic acid, hydroxyphenylhexanoic acid, or hydroxyphenylalanine. Amino alcohols such as ethanolamine.

In some embodiments, the ligand for the quantum dot material includes a ligand for cross-linking between the quantum dots under light irradiation, such as mono-2-(Methacryloyloxy)ethyl succinate.

In some embodiments, the first solvent, the second solvent, or the third solvent which as the developer includes at least one of a polar solvent or a non-polar solvent.

Non-polar solvents include hydrocarbon solvents, e.g. alkanes, olefins or alkynes, preferably hydrocarbon solvents with carbon atoms 6-40. Alkanes such as straight-chain alkanes, branched-chain alkanes, cycloalkanes or alkylbenzenes may be enumerated as at least one of octane, cyclohexane, tetradecane, toluene, octylbenzene and mixtures thereof.

In some embodiments, the polar solvent includes at least one of an alkyl alcohol solvent, an ether solvent, an acetal solvent, a halogenated hydrocarbon solvent, an ester solvent, and a nitrogen-containing compound solvent.

Alkyl alcohol solvent includes straight chain alkyl alcohol or branched chain alkyl alcohol, which can be listed as methanol, ethanol, propylene glycol, propanetriol and other polyol; ether and acetal solvent includes alcohol ethers such as ethylene glycol dimethyl ether, diethylene glycol dimethyl ether, diethylene glycol diethyl ether, diethylene glycol methyl ethyl ether, diethylene glycol dibutyl ether, triethylene glycol dimethyl ether, tetraethylene glycol dimethyl ether, glycerol ether and so on; halogenated hydrocarbon solvent includes chloroform, dichloromethane and so on; ester solvent includes propylene glycol monomethyl ester, propylene glycol methyl ether acetate, ethyl acetate, ethyl benzoate, etc.; nitrogen-containing compound solvent such as acetonitrile.

In some embodiments, the first material layer, the second material layer, or the third material layer of the present disclosure includes a photosensitive material, the photosensitive material including at least one of a photosensitive cross-linker, a photopolymerization initiator, and a photoacid generator. In some embodiments, at least one of the first material layer, the second material layer, or the third material layer of the present disclosure does not include a photosensitive material; or the first light emitting unit, the second light emitting unit, or the third light emitting unit is not formed by means of exposure (lithography). It should be understood that the expression “does not include a photosensitive material” in the present disclosure means that the first material layer, the second material layer, or the third material layer absolutely does not include a photosensitive material or relatively does not include a photosensitive material, and “relatively does not include a photosensitive material” means that the photosensitive material in the first material layer, the second material layer, or the third material layer does not exercise its photosensitive function.

In some embodiments, the photosensitive cross-linker includes at least one of an azide compound and a free radical photoinitiator.

In some embodiments, the photosensitive cross-linker includes an azide compound, such as a phenyl azide compound, such as (1E, 4E)-1,5-bis(4-azido-2,3,5,6-tetrafluorophenyl) penta-1,4-dien-3-one.

In some embodiments, the photosensitive cross-linker includes a free radical photoinitiator, such as ethyl phenyl(2,4,6-trimethylbenzoyl)phosphinate.

In some embodiments, the first material layer, the second material layer, or the third material layer has a solvent that dissolves the corresponding luminescent material, the solvent will be removed after the exposure treatment, such as by means of heat evaporation. The solvent for dissolving the luminescent material has the same polarity as the corresponding luminescent material.

In some embodiments, the concentration of the quantum dot material is 1 to 50 wt % by the total mass of the material layer (including the solvent). For example, the concentration of the quantum dot material is 20 to 30 wt %, such as the concentration of the quantum dot material may be any value or a range consisting of any two values among 1 wt %, 5 wt %, 10 wt %, 15 wt %, 20 wt %, 25 wt %, 30 wt %, 35 wt %, 40 wt %, 45 wt %, 50 wt %. In some embodiments, the mass percent of the quantum dot material is 50 to 100% in terms of the total mass of the light emitting unit.

In some embodiments, the mass percent of the photosensitive material is 0.01 to 2 wt % by the total mass of the material layer (including the solvent), such as the mass percent of the photosensitive material may be any value or a range consisting of any two values among 0.02 wt %, 0.05 wt %, 0.06 wt %, 0.08 wt %, 1 wt %, 1.2 wt %, 1.5 wt %, 1.8 wt %.

In some embodiments, the substrate 100 of the present disclosure has a plurality of isolation structures 101, and the light emitting layer 300 is divided into a plurality of light emitting units by the isolation structures 101. In some other embodiments, the isolation structures have a first surface 110, and the material of the first surface 110 is amphiphilic, and the surface of the isolation structures of the present disclosure is made of amphiphilic material, which can increase the compatibility between the isolation structures 101 and the luminescent material and improve the overall performance of the light emitting device. In addition, the height of the isolation structure 101 may be designed according to actual needs, and in some embodiments, the height of the isolation structure 101 may be lower than that of the light emitting layer 300. In some embodiments, the amphiphilic material may be listed as an amphiphilic polyurethane material.

In some embodiments, a first functional layer 500 is provided between the first electrode 200 and the light emitting layer 300, the first functional layer 500 including at least one of a hole injection layer, a hole transport layer, a hole blocking layer, an electron injection layer, an electron transport layer, an electron blocking layer, and a buffer layer. A second functional layer 600 is provided between the light emitting layer 300 and the second electrode 400, the second functional layer 600 including at least one of a hole injection layer, a hole transport layer, a hole blocking layer, an electron injection layer, an electron transport layer, an electron blocking layer, and a buffer layer. In some structures of the light emitting device, the first functional layer 500 includes a hole injection layer 501 and a hole transport layer 502, and the second functional layer 600 includes an electron transport layer.

Taking the first electrode 200 as an anode as an example, the first functional layer 500 is provided on top of the first electrode 200, the hole injection layer 501 may include (3,4-ethylenedioxythiophene)/poly(styrene p-sulfonate) (PEDOT/PSS), and the hole transport layer 502 may include N-vinylcarbazole (PVK), poly(N,N′-bis(4-butylphenyl)-N,N′-bis(phenyl)benzidine) (poly-TPD), 4,4′-N,N′-dicarbazolyl-biphenyl (CBP), 4,4-bis[N-(1-naphthyl)-N-phenylamino]biphenyl (NPD), or poly(9,9′-dioctylfluorene-co-N-(4-butyl phenyl)diphenylamine (TFB), and other organic materials, or the hole transport layer 502 may include an inorganic material such as NiO or MoO₃. Those skilled in the art will understand that a wide variety of methods may be used to prepare the first functional layer 500, the thickness of the hole injection layer 501 may be in a range of tens to hundreds of nanometers, such as 20-300 nanometers, preferably 30-150 nanometers; the thickness of the hole transport layer 502 may be in a range of tens to hundreds of nanometers, such as 10-200 nanometers, preferably 15-100 nanometers. The hole transport layer may have i) a monolayer structure including a single layer utilizing a single substance, ii) a monolayer structure including a single layer including a plurality of substances that are different from each other, or iii) a multilayer structure including a plurality of layers including a plurality of substances that are different from each other.

The second functional layer 600 includes an electron transport layer, and the electron transport layer can include 1,4,5,8-naphthalene-tetracarboxylic acid dianhydride (NTCDA), bathopperine (BCP), tris[3-(3-pyridinyl)-based] borane (3TPYMB), LiF, tris(8-hydroxyquinoline)aluminum (Alq₃), tris(8-hydroxyquinoline) gallium (Gaq₃), tris(8-hydroxyquinoline) indium (Inq₃), bis(8-hydroxyquinoline) zinc (Znq₂), bis(2-(2-hydroxyphenyl)benzothiazolyl) zinc (Zn(BTZ)₂), bis(10-hydroxybenzo[h]quinoline) beryllium (BeBq₂), 8-(4-(4,6-bis(naphthalen-2-yl)-1,3,5-triazin-2-yl)phenyl) quinolone (ET204), lithium 8-hydroxyquinoline (Liq), n-type metal oxides (e.g., ZnO, HfO₂, etc.), or combinations thereof, but not limited thereto. The electron transport layer may include metal oxide nanoparticles such as ZnO, ZnMgO, or combinations thereof. The metal oxide nanoparticles may include Zn₁₋ₓMₓO (wherein M is Mg, Ca, Zr, W, Li, Ti, Y, Al, or a combination thereof, and 0≤x≤0.5). In said chemical formula, x may be greater than or equal to about 0.01 and less than or equal to about 0.3, e.g., less than or equal to about 0.25, less than or equal to about 0.2, or less than or equal to about 0.15. The thickness of the electron transport layer may be in a range of a few tens to a few hundreds of nanometers, e.g., 10-400 nanometers, preferably 20-100 nanometers. The electron transport layer may have i) a single layer structure including a single layer utilizing a single substance, ii) a single layer structure including a plurality of single layers including a plurality of substances that are different from each other, or iii) a multilayer structure including a plurality of layers including a plurality of substances that are different from each other. A second electrode 400 is provided above the second functional layer 600, the second electrode 400 being a cathode, and the second electrode 400 may include Mg, Ca, Na, Ti, In, Ir, Li, Al, Ag, Zn, Pb, Ce, Ba, LiF/Al, LiO₂/Al, LiF/Ca, or BaF₂/Ca, etc., and furthermore, an electron injection layer may also be formed between the electron transport layer and the second electrode 400.

In some embodiments, the individual functional layers of the light emitting device of the present disclosure may be prepared by: for example, spin-coating, spraying, casting, ink-jet printing, or LB (Langmuir-Blodgett), and other well-known methods.

In some specific embodiments, the light emitting layer 300 of the present disclosure is prepared from a material dispersed with quantum dots, and specific preparation method that may be enumerated is photolithography, spin-coating or whole-surface coating.

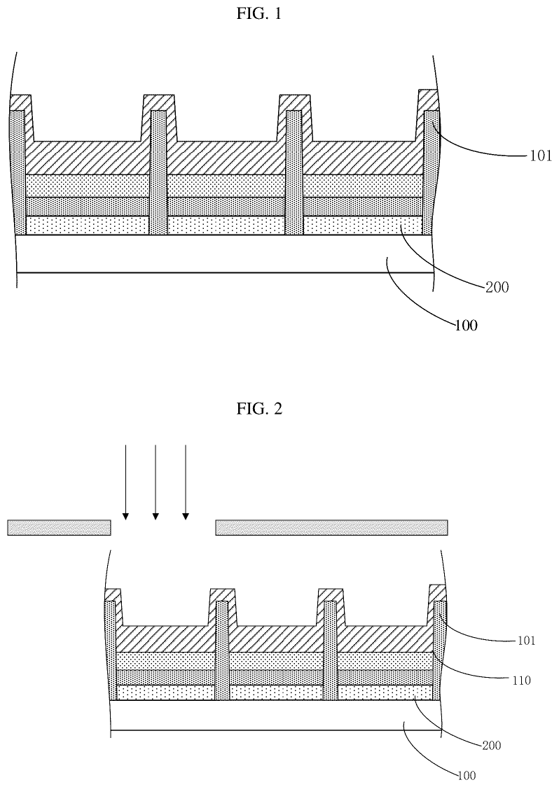

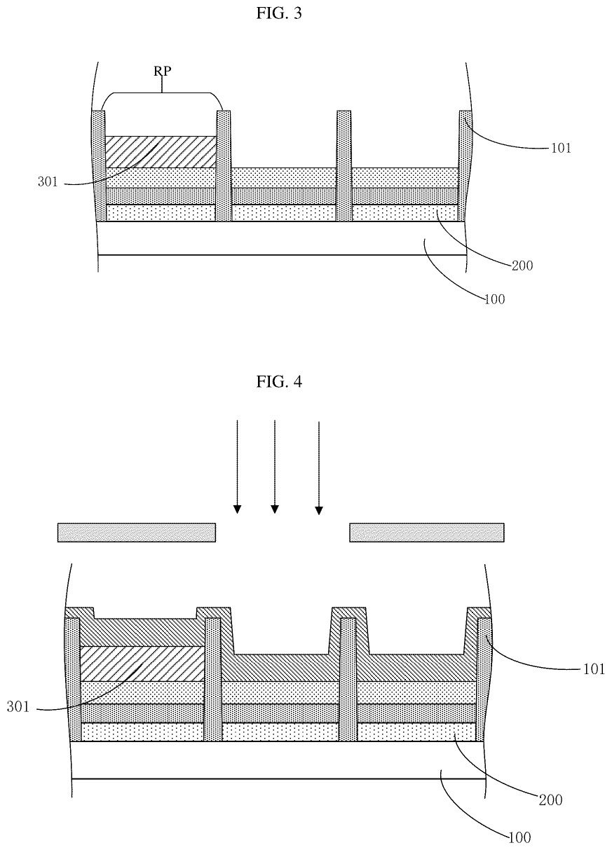

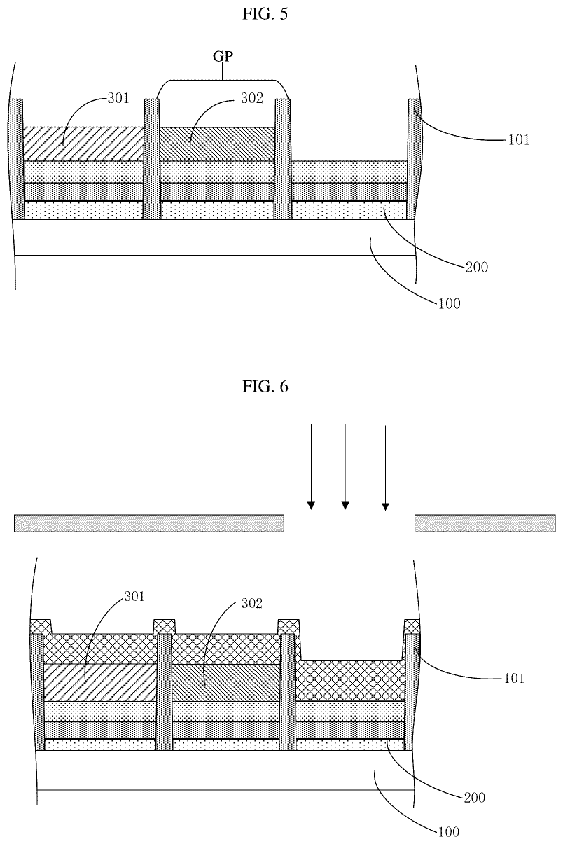

Taking the light emitting device with RGB pixel areas as an example, as shown in FIGS. 1 to 7, the preparation step of the light emitting device of the present disclosure includes:
a patterned mask is disposed above the first material layer including a photosensitive material (photosensitive cross-linker), and light is irradiated from above the patterned mask to expose the photosensitive material. That is, in the photosensitive material, an exposure area is formed at a position where the patterned mask is not set above, and a non-exposure area is formed at a position where the patterned mask is set above. For example, an i-line (wavelength is 365 nm) may be used for the exposure light, but it may also be selected appropriately according to the material. Furthermore, from the viewpoint of improving the pattern accuracy and reducing the film loss, the exposure amount is preferably 20 mJ/cm² or more. In addition, from the viewpoint of suppressing the increase in tact time and reducing damage to other members, the exposure amount is preferably 1000 mJ/cm² or less.

At this time, the patterned mask is provided above the green pixel area GP, the blue pixel area BP. As a result, the light irradiated into the green pixel area GP and the blue pixel area BP is blocked by the patterned mask, thus non-exposure area is formed. Accordingly, the photosensitive material formed only on the hole transport layer in the red pixel area RP is exposed and becomes the exposure area, and the photosensitive material in the exposure area is cross-linked and becomes the light emitting unit. Optionally, after exposure, a drying process may be performed to remove the solvent that dissolves the quantum dot material.

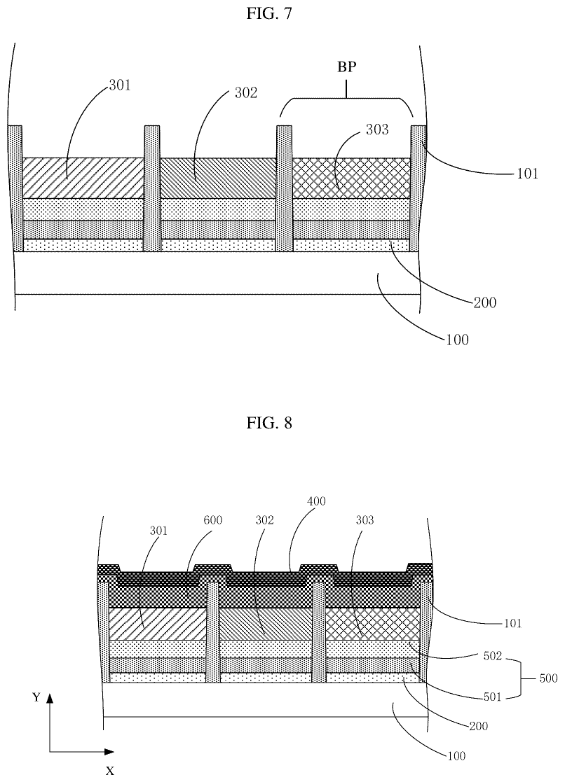

Next, the first material layer is washed with the first solvent as the developer, the developer being, for example, toluene or PGME, and the polarity of the first solvent is the same as that of the first luminescent material. The photosensitive material is a negative type photosensitive material and after exposure it becomes insoluble in the developer. Accordingly, the light emitting layer with the photosensitive material exposed is not dissolved in the developer, but remains on top of the hole transport layer. Accordingly, the light emitting layer having RQD is formed only on the red pixel area RP to form the first light emitting unit 301. Optionally, after developing, a drying process may be performed again. The above steps can be repeated to form the second light emitting unit 302 having GQD in the green pixel area GP, and the third light emitting unit 303 having BQD in the blue pixel area BP. As a result, the structure shown in FIG. 7 below is obtained. The RGB three-color pattern is only an example, and it may be a combination of other colors.

In some embodiments, for the first light emitting unit 301, a non-polar quantum dot material is selected, for the second light emitting unit 302, a polar quantum dot material is selected, and for the third light emitting unit 303, a polar quantum dot material is selected. The first light emitting units 301 including the non-polar quantum dot material is prepared, the first light emitting units 301 being disposed in a first pixel area, a second pixel area, and a third pixel area, and a coating layer including the polar quantum dot material is disposed on the first light emitting units, and a polar solvent is used to develop the light emitting units to obtain the second light emitting unit 302, at this time, because the first light emitting unit 301 has been cured, the polar solvent developer is unable to dissolve the non-polar quantum dots of the first light emitting unit 301, and a coating layer including the polar quantum dot material is subsequently disposed, and a polar solvent is used to develop the light emitting unit to obtain the third light emitting unit 303, and as the first light emitting unit 301 and the second light emitting unit 302 have been cured, the polar quantum dots in the second light emitting unit 302 remain protected.

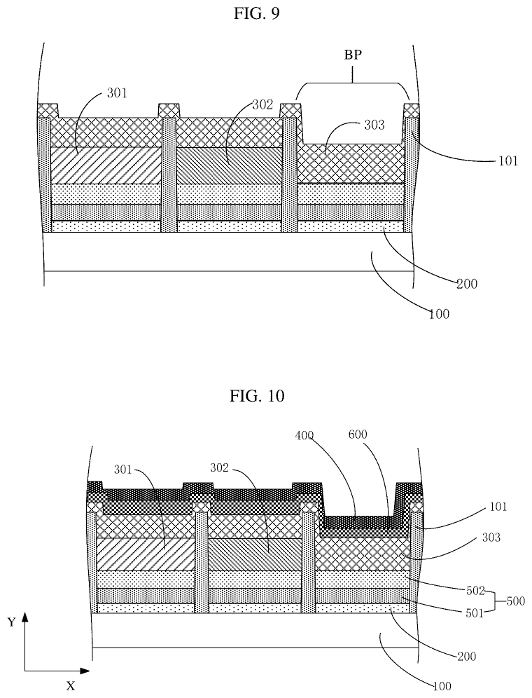

As shown in FIGS. 9 and 10, in some embodiments, the light emitting layer 300 may be prepared by the following methods.

A first functional layer 500 is prepared on the substrate 100 having a first electrode 200; the first electrode 200 is an anode, and the first functional layer 500 includes a hole injection layer 501 and a hole transport layer 502; a first material layer including polar red quantum dots is coated on the first functional layer 500, and the thickness of the first material layer is preferably 10 nm or more, for example, the thickness of the first material layer is 15~50 nm, the thickness of the first material layer is more preferably 20 nm or more; the first material layer includes a photosensitive material, or in the first material layer, the red quantum dots are used as the photosensitive materials, then there is no need to add in additional photosensitive material; exposure to form an exposure area and a non-exposure area at the location of the first material layer; a polar solvent is employed as the first solvent, the first material layer in the non-exposure area is removed, and the first light emitting unit 301 is formed.

Using the same preparation method, the second light emitting unit 302 can be prepared, wherein the second luminescent material is a non-polar quantum dot material, the second luminescent material layer is washed with a non-polar second solvent as the developer, the second material layer in the non-exposure area is removed, and the second material layer in the exposure area is retained to form the second light emitting unit 302.

Repeating the above steps, the third material layer including blue quantum dots is sequentially formed on the substrate 100 on which the first light emitting unit 301 and the second light emitting unit 302 are formed, the third material layer does not include a photosensitive material, and after the coating is completed, no exposure is carried out, and the third light emitting unit 303 is directly formed, as shown in FIG. 9. Subsequently, a second functional layer 600 and a second electrode 400 are formed above the light emitting layer 300 sequentially from the bottom to the top, the second functional layer 600 being an electron transport layer, and the second electrode 400 being a cathode, whereby a structure as shown in FIG. 10 is obtained. In this structure, the third light emitting unit 303 overlaps with the orthographic projections of the first light emitting unit 301 and the second light emitting unit 302 on the substrate 100, and the third light emitting unit 303 disposed in the blue pixel area (BP) emits blue light without the need for exposure and development, which reduces the loss of the performance of the blue light emitting layer, meanwhile reduces the effect of the rinsing and development on the luminous efficiency of the first light emitting unit 301 and the second light emitting unit 302 which have already been formed.

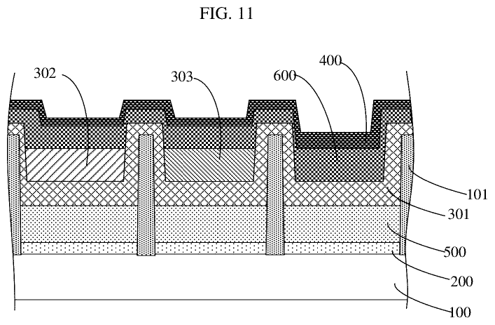

As shown in FIG. 11, in some embodiments, a first functional layer 500 is prepared on the substrate 100 having the first electrode 200; the first electrode 200 is a cathode, and the first functional layer 500 is an electron transport layer; a third material layer including polar blue quantum dots is coated on the first functional layer 500, and a thickness of the third material layer is preferably 10 nm or more, such as a thickness of the third material layer of 15 to 50 nm, the thickness of the third material layer is more preferably 20 nm or more, and the third material layer does not include a photosensitive material; the formed third material layer will not be subjected to an exposure treatment, the third light emitting unit 303 is formed.

The first light emitting unit 301 is prepared on top of the formed third material layer, the first luminescent material in the first material layer is a non-polar red quantum dot material, the first material layer includes a photosensitive material; or in the first material layer, the red quantum dots act as the photosensitive material, then there is no need to add in additional photosensitive material; then the exposure is carried out, and exposure area and non-exposure area are formed in the location where the first material layer is located, and a non-polar solvent is used as the first solvent, the first material layer is removed in the non-exposure area, and the first light emitting unit 301 is formed.

The above preparation step of the first light emitting unit 301 is repeated, and the second light emitting unit 302 is prepared on the substrate 100 on which the third light emitting unit 303 and the first light emitting unit 301 are formed, as shown in FIG. 11. Subsequently, a second functional layer 600 and a second electrode 400 are sequentially formed on top of the light emitting layer 300, the second functional layer 600 including a hole transport layer and a hole injection layer, and the second electrode 400 being an anode, whereby a structure as shown in FIG. 11 is obtained, the third light emitting unit 303 overlapping with the orthographic projections of the first light emitting unit 301 and the second light emitting unit 302 on the substrate 100, the first light emitting unit 301 and the second light emitting unit 302 are disposed on the top of the third light emitting unit 303, and the third light emitting unit 303 located in the blue pixel area (BP) emits blue light.

Moreover, in the embodiments of the present disclosure, the RGB tricolor pattern and the sequence of preparation are only examples, and may be a combination of other colors.

Embodiments of the present disclosure provide an electronic apparatus, the above-mentioned light emitting device, or, the light emitting device obtained by the method of preparing the above-mentioned light emitting device.

In some embodiments, the electronic apparatus is prepared by the following method: a capping layer capable of transmitting light can be formed on the second electrode 400. Optionally, an additional substrate can be provided on top of the light emitting device to be opposed to the substrate 100 for encapsulation. By applying the above-described light emitting device to the electronic apparatus, the electronic apparatus having excellent light emitting performance can be obtained. The electronic apparatus may be a large electronic apparatus, such as a TV, a monitor, and/or an outdoor billboard. In other embodiments, the electronic apparatus may be a small or medium-sized electronic apparatus, such as a personal computer, a laptop computer, a personal digital terminal, a car navigation system, a game console, a smart phone, a tablet computer, and/or a camera.

In order to further minimize the impact of the development process on the device performance, embodiments of the present disclosure provide light emitting layer with quantum dots of different polarities, and a non-polar quantum dot layer prepared by the following method can be enumerated.

Red quantum dot layer: the parameters of 2000 rpm, 45 s are set to spin-coat the quantum dot solution on the hole transport layer, in which the red quantum dots are CdSe/ZnS, the ligand is oleic acid, and the photosensitive cross-linker is (1E,4E)-1,5-bis(4-azido-2,3,5,6-tetrafluorophenyl) penta-1,4-dien-3-one, a mass concentration of the quantum dots in the solution (toluene) is 15 mg/mL. UV exposure intensity is 300 mJ/cm², and the film is developed using toluene after exposure, and after development is completed, it is annealed at 120° C. for 20 min to form a patterned red quantum dot light emitting layer.

Green quantum dot layer: the parameters of 2000 rpm, 45 s are set to spin-coat the quantum dot solution on the hole transport layer, in which the green quantum dots are CdSe/ZnS, the ligand is oleic acid, and the photosensitive cross-linker is (1E,4E)-1,5-bis(4-azido-2,3,5,6-tetrafluorophenyl) penta-1,4-dien-3-one, and the mass concentration of the quantum dots in the solution (toluene) is 15 mg/mL, and the UV exposure intensity is 300 mJ/cm², and the film is developed using toluene after exposure, and after development is completed, annealing is performed at 120° C. for 20 min to form a patterned green quantum dot light emitting layer.

Blue quantum dot layer: the parameters of 2000 rpm, 45 s are set to spin-coat the quantum dot solution on the hole transport layer, in which the blue quantum dots are CdSe/ZnS, the ligand is oleic acid, and the photosensitive cross-linker is (1E,4E)-1,5-bis(4-azido-2,3,5,6-tetrafluorophenyl) penta-1,4-dien-3-one, mass concentration of the quantum dot in the solution (toluene) is 15 mg/mL. UV exposure intensity is 300 mJ/cm², after exposure toluene is used to develop the film, after the development is completed, annealing at 120° C. for 20 minutes to form a patterned blue quantum dot light emitting layer.

The polar quantum dot layer is prepared by the following method.

Red quantum dot layer: the parameters of 2000 rpm, 45s are set to spin-coat the quantum dot solution on the hole transport layer, in which the red quantum dots are CdSe/ZnS, the ligand is succinic acid mono-2-(2-methyl-propenoyl)oxyethyl ester, the mass concentration of the quantum dots in the solution is 15 mg/mL, and the photosensitive cross-linker is 2,4,6-trimethylbenzoylphenylphosphonic acid ethyl ester, which is dissolved in the Propylene Glycol Methyl Ether (PGME) solution. UV exposure intensity is 300 mJ/cm², after exposure, the film is developed using PGME, and after development is completed, it is annealed at 120° C. for 20 minutes to form a patterned red quantum dot light emitting layer.

Green quantum dot layer: the parameters of 2000 rpm, 45s are set to spin-coat the quantum dot solution on the hole transport layer, in which the green quantum dots are CdSe/ZnS, the ligand is succinic acid mono-2-(2-methyl-propenoyl)oxyethyl ester, mass concentration of the quantum dots in the solution is 15 mg/mL, and the photosensitive cross-linker is 2,4,6-trimethylbenzoylphenylphosphonic acid ethyl ester, dissolved in the PGME solution. UV exposure intensity is 300 mJ/cm², after exposure, the film is developed using PGME, and after development is completed, it is annealed at 120° C. for 20 minutes to form a patterned green quantum dot light emitting layer.

Blue quantum dot layer: the parameters of 2000 rpm, 45s are set to spin-coat the quantum dot solution on the hole transport layer, in which the blue quantum dots are CdSe/ZnS, the ligand is succinic acid mono-2-(2-methyl-propenoyl)oxyethyl ester, mass concentration of the quantum dots is 15 mg/mL, and the photosensitive cross-linker is 2,4,6-trimethylbenzoylphenylphosphonic acid ethyl ester, dissolved in the PGME solution. UV exposure intensity is 300 mJ/cm², after exposure, the film is developed using PGME, and after development is completed, it is annealed at 120° C. for 20 min to form a patterned blue quantum dot light emitting layer.

Other functional layers can be prepared by the following methods.

Hole injection layer: a cleaned ITO glass substrate is spin-coated with PEDOT: PSS respectively in air at a speed of 3500 r/min for 45 seconds; after the spin-coating is completed, it is placed in the air for annealing at an annealing temperature of 150° C. for 30 minutes; after annealing is completed, the sample is quickly transferred to a glove box in a nitrogen atmosphere.

Hole transport layer: the hole injection layer is continued to be spin-coated with a hole transport layer of 8 mg/mL of TFB at a rotational speed of 3000 r/min for 45 s. After completion of the spin-coating, the layer is annealed in a glove box at an annealing temperature of 150° C. for 20 min.

Zinc oxide electron transport layer: the parameters of 3000 rpm, 30 s are set to spin-coat a solution of zinc oxide nanocrystals (30 mg/mL, ethanol) on the quantum dot layer.

The other electrode can be prepared by the following method: the prepared sample is placed into the vacuum chamber and the top electrode is vaporized. The vaporization rate is controlled within the range 0.2-0.4 Å/sec for the first 10 nm, and the vaporization rate is increased to about 1.0-2.0 Å/sec after reaching 10 nm. The thickness of the prepared silver electrode is 100 nm.

The following Examples 1-2 and Comparative Example 1 were prepared in the order of RGB, and a cleaned ITO TFT substrate glass was prepared, and a light emitting device with an ITO electrode/hole injection layer PEDOT: PSS/hole transport layer TFB/quantum-dot layer/zinc oxide electron transport layer/Ag electrode structure was prepared with reference to the above-listed methods.

The sequence of preparation light emitting units for both Examples 1-2 and Comparative Example 1 is RGB.

Example 1: the following materials were selected for the process of light emitting unit formation: polar red quantum dot layer, PGME (as quantum dot solvent and developer), non-polar green quantum dot layer, toluene (as quantum dot solvent and developer); and non-polar blue quantum dot layer, toluene (as quantum dot solvent and developer), respectively.

Example 2: the following materials were selected for the process of light emitting unit formation: polar red quantum dot layer, PGME (as quantum dot solvent and developer); polar green quantum dot layer, PGME (as quantum dot solvent and developer); non-polar blue quantum dot layer, toluene (as quantum dot solvent and developer), respectively.

Comparative Example 1: the following materials were selected for the process of light emitting unit formation: a non-polar red quantum dot layer, toluene (as quantum dot solvent and developer); a non-polar green quantum dot layer, toluene (as quantum dot solvent and developer); and a non-polar blue quantum dot layer, toluene (as quantum dot solvent and developer), respectively.

The performance test results of the external quantum efficiency (EQE) of the light emitting device (QLED) of Examples 1-2 and Comparative Example 1 are shown in Table 1. External Quantum Efficiency (EQE): a Keithley 2400 power supply was used to provide voltage input to the light emitting device and obtain the corresponding current output, and the brightness of the QLED was measured using an integrating sphere (FOIS-1) in combination with a spectrometer (QE-pro) of Ocean Optics. The external quantum efficiency of the light emitting devices were obtained based on the parameters of current density and brightness, and the higher the external quantum efficiency, the better the light emitting performance.

TABLE 1

| | Before | After the first | After the second | After the third |
|---|---|---|---|---|
| | development of | development of | development of | development of |
| | the red light | the red light | the red light | the red light |
| | emitting layer | emitting layer | emitting layer | emitting layer |
| Example 1 | 15.2% | 12.5% | 12.3% | 12.2% |
| Example 2 | 15.5% | 13.0% | 11.3% | 11.1% |
| Comparative | 15.6% | 12.8% | 11.0% | 9.5% |
| Example 1 | | | | |

From the results in Table 1, it can be seen that for the quantum dot material in the first material layer, the development process has damage to the EQE, the development damage of the same polarity solvent is large, while in the preparation process, the orthogonal solvents with different polarity are used then the development damage to the light emitting units is small. The red quantum dot material in the first material layer had undergone three times of solvent development. The first development with all the corresponding solvents, efficiency drops of Examples 1-2 and the Comparative Example 1 are basically the same. For the device of Comparative Example 1 which underwent three times of development using the corresponding polar solvent, each time its loss is relatively large. It can be seen that Example 1 has the first development with the corresponding solvent, and the second development with the orthogonal solvent, and Example 2 has two corresponding solvent developments, and one orthogonal solvent, and from the above data, the external quantum efficiency of the red light emitting layer of Example 1 is superior.

The sequence of preparing light emitting units for Examples 3-4 and Comparative Example 2 is GRB.

Example 3: the following materials were selected for the process of light emitting unit formation: polar green quantum dot layer, PGME (as quantum dot solvent and developer), non-polar red quantum dot layer, toluene (as quantum dot solvent and developer); and non-polar blue quantum dot layer, toluene (as quantum dot solvent and developer), respectively.

Example 4: the following materials were selected for the process of light emitting unit formation: polar green quantum dot layer, PGME (as quantum dot solvent and developer); polar red quantum dot layer, PGME (as quantum dot solvent and developer); and non-polar blue quantum dot layer, toluene (as quantum dot solvent and developer), respectively.

Comparative Example 2: the following materials were selected in the process for the formation of light emitting units: a non-polar green quantum dot layer, toluene (as quantum dot solvent and developer); a non-polar red quantum dot layer, toluene; and a non-polar blue quantum dot layer, toluene (as quantum dot solvent and developer), respectively.

The external quantum efficiency (EQE) performance test results with QLEDs of Examples 3 to 4 and Comparative Example 2 are shown in Table 2.

TABLE 2

| | Before | After the first | After the second | After the third |
|---|---|---|---|---|
| | development of | development of | development of | development of |
| | the green light | the green light | the green light | the green light |
| | emitting layer | emitting layer | emitting layer | emitting layer |
| Example 3 | 14.7% | 11.9% | 11.7% | 11.6% |
| Example 4 | 14.9% | 12.1% | 9.5% | 9.3% |
| Comparative | 14.8% | 12.1% | 9.7% | 7.9% |
| Example 2 | | | | |

The sequence of preparing light emitting units in Examples 5-6 and in Comparative Example 3 is BRG.

Example 5: the following materials were selected for the light emitting unit: polar blue quantum dot layer, PGME (as quantum dot solvent and developer), non-polar red quantum dot layer, toluene (as quantum dot solvent and developer); and non-polar green quantum dot layer, toluene (as quantum dot solvent and developer), respectively.

Example 6: the following materials were selected for the light emitting unit: polar blue quantum dot layer, PGME (as quantum dot solvent and developer); polar red quantum dot layer, PGME (as quantum dot solvent and developer); and non-polar green quantum dot layer, toluene (as quantum dot solvent and developer), respectively.

For Comparative Example 3: the following materials were selected for the light emitting units: a non-polar blue quantum dot layer, toluene (as quantum dot solvent and developer); a non-polar red quantum dot layer, toluene (as quantum dot solvent and developer); and a non-polar green quantum dot layer, toluene (as quantum dot solvent and developer), respectively.

The external quantum efficiency (EQE) performance test results with QLEDs of Examples 5 to 6 and Comparative Example 3 are shown in Table 3.

TABLE 3

| | Before | After the first | After the second | After the third |
|---|---|---|---|---|
| | development of | development of | development of | development of |
| | the blue light | the blue light | the blue light | the blue light |
| | emitting layer | emitting layer | emitting layer | emitting layer |
| Example 5 | 12.0% | 10.1% | 9.8% | 9.6% |
| Example 6 | 12.2% | 10.3% | 8.0% | 7.7% |
| Comparative | 12.5% | 10.7% | 8.4% | 6.3% |
| Example 3 | | | | |

The above provides a detailed description of a light emitting device, preparation method and electronic apparatus provided in this disclosure, and specific examples are applied herein to illustrate the principles and implementation of this disclosure, and the above description of the examples is only used to help understand the method of this disclosure and its core ideas; at the same time, for the person having ordinary skill in the art, based on the ideas of this disclosure, there will be changes in the specific implementation and application scope. At the same time, for the technical personnel in the field, according to the ideas of this disclosure, there will be changes in the specific implementation and application scope.

1. A method of preparing a light emitting device, the method comprising:
providing a substrate with a first electrode;
forming a light emitting layer on a side of said first electrode away from said substrate;
wherein a preparation of said light emitting layer comprising:
forming a first material layer comprising a first luminescent material on top of said first electrode, forming an exposure area and a non-exposure area in said first material layer, and removing at least a portion of said exposure area or at least a portion of said non-exposure area of said first material layer by a first solvent to obtain a first light emitting unit;
forming a second material layer comprising a second luminescent material on top of said first electrode, forming an exposure area and a non-exposure area in said second material layer, and removing at least a portion of said exposure area or at least a portion of said non-exposure area of the second material layer by a second solvent to obtain a second light emitting unit;
forming a second electrode on top of said light emitting layer;
said first light emitting unit and said second light emitting unit are disposed along a first direction X of said substrate, said first light emitting unit is used to emit light in a first wavelength range, said second light emitting unit is used to emit light in a second wavelength range, said first wavelength range being different from said second wavelength range, and a polarity of said second solvent being different from a polarity of said first luminescent material.

2. The method of preparing a light emitting device according to claim 1, wherein, the preparation of said light emitting layer further comprises: forming a third material layer comprising a third luminescent material on top of said first electrode.

3. The method of preparing a light emitting device according to claim 2, wherein, forming an exposure area and a non-exposure area in said third material layer, and removing at least a portion of said exposure area or at least a portion of said non-exposure area of said third material layer by a third solvent to obtain a third light emitting unit;
said third light emitting unit is used to emit light in a third wavelength range, said third wavelength range being different from said first wavelength range and said second wavelength range;
a polarity of said third solvent being different from the polarity of said first luminescent material and the polarity of said second luminescent material.

4. The method of preparing a light emitting device according to claim 3, wherein said first light emitting unit, said second light emitting unit and said third light emitting unit are disposed along the first direction X.

5. The method of preparing a light emitting device according to claim 3, wherein said first luminescent material, said second luminescent material or said third luminescent material comprises a quantum dot material.

6. The method of preparing a light emitting device according to claim 5, wherein said quantum dot material comprises at least one of CdSe/ZnSe, CdSe/ZnS, CdSe/ZnSe/ZnS, CdS/ZnS, CdS/ZnS, ZnTeSe/ZnS, InP/ZnSe/ZnS and InP/ZnS.

7. The method of preparing a light emitting device according to claim 5, wherein a ligand of said quantum dot material comprises at least one of an alkyl carboxylic acid, an alkyl phosphonic acid, an alkyl phosphinic acid, an alkyl mercaptan, an alkyl mercaptan, an alkyl mercaptan, an alkyl thiol, an alkyl amine, an acrylate-substituted acid, a halogen, a mercapto alcohol, a carboxy alcohol, and an amino alcohol.

8. The method of preparing a light emitting device according to claim 3, wherein said first solvent, said second solvent or said third solvent comprises at least one of a hydrocarbon solvent, an alkyl alcohol solvent, an ether solvent, an acetal solvent, a halogenated hydrocarbon solvent, an ester solvent and a nitrogen-containing compound solvent.

9. The method of preparing a light emitting device according to claim 3, wherein the polarity of said first luminescent material is different from said second solvent and said third solvent.

10. A method of preparing a light emitting device according to claim 3, wherein said first material layer, said second material layer or said third material layer comprises at least one of a photosensitive cross-linker, a photopolymerization initiator and a photoacid generator.

11. The method of preparing a light emitting device according to claim 10, wherein said photosensitive cross-linker comprises at least one of an azide compound and a free radical photoinitiator.

12. The method of preparing a light emitting device according to claim 1, wherein said substrate has a plurality of isolation structures and said light emitting layer is divided into a plurality of light emitting units by said isolation structures.

13. The method of preparing a light emitting device according to claim 12, wherein said isolating structure has a first surface, the material of said first surface being amphiphilic.

14. The method of preparing a light emitting device according to claim 1, wherein, forming a first functional layer between said first electrode and said light emitting layer, said first functional layer comprising at least one of a hole injection layer, a hole transport layer, a hole blocking layer, an electron injection layer, an electron transport layer, an electron blocking layer and a buffer layer.

15. The method of preparing a light emitting device according to claim 1, wherein, forming a second functional layer between said light emitting layer and said second electrode, said second functional layer comprising at least one of a hole injection
layer, a hole transport layer, a hole blocking layer, an electron injection layer, an electron transport layer, an electron blocking layer and a buffer layer.

16. The method of preparing a light emitting device according to claim 5, wherein, a concentration of said quantum dot material is 1 to 50 wt %.

17. A light emitting device, wherein said light emitting device is prepared by the method as claimed in claim 1.

18. An electronic apparatus, comprising the light emitting device as claimed in claim 17.
